(19) United States
(12) Patent Application Publication
(10) Pub. No.: US 2022/0208994 A1
(43) Pub. Date: Jun. 30, 2022

(54) METHOD FOR FABRICATING SEMICONDUCTOR STRUCTURE, AND SEMICONDUCTOR STRUCTURE

(71) Applicant: CHANGXIN MEMORY TECHNOLOGIES, INC., Hefei (CN)

(72) Inventors: Jie BAI, Hefei (CN); Kang YOU, Hefei (CN)

(21) Appl. No.: 17/406,096

(22) Filed: Aug. 19, 2021

Related U.S. Application Data
(63) Continuation of application No. PCT/CN2021/103699, filed on Jun. 30, 2021.

(30) Foreign Application Priority Data
Dec. 30, 2020 (CN) 202011630018.1

(51) Int. Cl. H01L 29/66; H01L 29/423; H01L 29/78

(52) U.S. Cl. CPC H01L 29/66734; H01L 29/7813; H01L 29/4236

(57) ABSTRACT

The present disclosure relates to a method for fabricating a semiconductor structure and the semiconductor structure. The method includes: providing a substrate, the substrate comprising a cell region and a peripheral region positioned at a periphery of the cell region; forming a patterned mask layer on a surface of the substrate, the patterned mask layer being internally provided with a first opening pattern and a second opening pattern, the first opening pattern being positioned in the cell region to define a shape and a location of a wordline trench, and the second opening pattern being positioned in the peripheral region to define a shape and a location of a peripheral gate trench; etching the substrate based on the patterned mask layer to form the wordline trench in the cell region, and to synchronously form the peripheral gate trench in the peripheral region; and forming a buried wordline in the wordline trench, and synchronously forming a buried gate in the peripheral gate trench.

### CROSS REFERENCE TO RELATED APPLICATION

This application is a continuation of PCT/CN2021/103699, filed on Jun. 30, 2021, which claims priority to Chinese Patent Application No. 202011630018.1 titled “METHOD FOR FABRICATING SEMICONDUCTOR STRUCTURE, AND SEMICONDUCTOR STRUCTURE” and filed to the State Intellectual Property Office on Dec. 30, 2020, the entire contents of which are incorporated herein by reference.

### TECHNICAL FIELD

The present disclosure relates to the field of integrated circuit design and manufacturing technologies, and more particularly, to a method for fabricating a semiconductor structure and the semiconductor structure.

### BACKGROUND

With the rapid development of integrated circuit (IC) manufacturing processes, requirements for integration of semiconductor products are getting higher and higher. However, as the integration of the semiconductor products increases, sizes of semiconductor devices continue to decrease, which causes smaller and smaller gate sizes of peripheral circuits, more obvious short-channel effects, and higher probability of electric leakage.

A semiconductor memory device includes an array region and a peripheral region positioned at the periphery of the array region. The array region includes a cell region and a peripheral region positioned at the periphery of the cell region and configured for arranging various kinds of logic circuits. For example, the peripheral region configured for arranging various kinds of logic circuits may include a sensitive amplifier circuit, a switch control circuit, or a clock circuit, etc.

How to reduce the sizes of the semiconductor devices and ensure that the gate sizes of circuits in the peripheral region meet the requirements for circuit integration design while avoiding the increase of the short-channel effects and leakage current of the semiconductor devices has become one of technical problems to be solved urgently in the field of semiconductor manufacturing technologies.

### SUMMARY

According to embodiments of the present disclosure, there is provided a method for fabricating a semiconductor structure, and a semiconductor structure.

An aspect of the present disclosure provides a method for fabricating a semiconductor structure. The method includes:

providing a substrate, the substrate comprising a cell region and a peripheral region positioned at a periphery of the cell region;

forming a patterned mask layer on a surface of the substrate, the patterned mask layer being internally provided with a first opening pattern and a second opening pattern, the first opening pattern being positioned in the cell region to define a shape and a location of a wordline trench, and the second opening pattern being positioned in the peripheral region to define a shape and a location of a peripheral gate trench;

etching the substrate based on the patterned mask layer to form the wordline trench in the cell region, and to synchronously form the peripheral gate trench in the peripheral region; and

forming a buried wordline in the wordline trench, and synchronously forming a buried gate in the peripheral gate trench.

In the method for fabricating a semiconductor structure in the foregoing embodiments, a substrate is provided, wherein the substrate comprises a cell region and a peripheral region positioned at a periphery of the cell region. A patterned mask layer is formed on a surface of the substrate, wherein the patterned mask layer is internally provided with a first opening pattern and a second opening pattern. The first opening pattern is positioned in the cell region to define a shape and a location of a wordline trench, and the second opening pattern is positioned in the peripheral region to define a shape and a location of a peripheral gate trench. Next, the substrate is etched based on the patterned mask layer to form the wordline trench in the cell region, and synchronously the peripheral gate trench is formed in the peripheral region. Next, a buried wordline is formed in the wordline trench, and synchronously a buried gate is formed in the peripheral gate trench. In the present disclosure, a wordline in the cell region and a gate in the peripheral region at the periphery of the cell region are subject to single exposure and fabricated synchronously, which reduces fabrication costs compared with separately fabricating the gate in the peripheral region where an additional photomask is required. In the present disclosure, the wordline in the cell region and the gate in the peripheral region at the periphery of the cell region both are buried structures, such that it is ensured that the gate sizes of circuits in the peripheral region meet the requirements for circuit integration design while avoiding the increase of the short-channel effects and leakage current of the semiconductor devices.

Another aspect of the present disclosure provides a semiconductor structure, which includes:

a substrate, the substrate comprising a cell region and a peripheral region positioned at a periphery of the cell region;

a buried wordline, positioned in the cell region; and

a buried gate, positioned in the peripheral region.

In the semiconductor structure provided in the above embodiment, the wordline in the cell region and the gate in the peripheral region at the periphery of the cell region both are buried structures, such that it is ensured that the gate sizes of circuits in the peripheral region meet the requirements for circuit integration design while avoiding the increase of the short-channel effects and leakage current of the semiconductor devices.

### BRIEF DESCRIPTION OF THE DRAWINGS

To better describe and illustrate the embodiments and/or examples of those applications disclosed herein, one or more drawings may be referred to. The additional details or examples configured for describing the drawings should not be considered as limiting the scope of any of the disclosed applications, the currently described embodiments and/or examples, and the best mode of these applications currently understood.

FIG. 1 is a flowchart of a method for fabricating a semiconductor structure according to an embodiment of the present disclosure;

FIG. 2 is a schematic top view of a semiconductor structure according to an embodiment of the present disclosure;

FIG. 3 is a schematic top view showing structures of portions corresponding to a cell region 101 and a peripheral region 102 in FIG. 2;

FIG. 4a is a schematic structural diagram showing sections captured along directions A-A′, C-C′ and E-E′ in FIG. 3 for a structure obtained in Step S2 of a method for fabricating a semiconductor structure according to an embodiment of the present disclosure;

FIG. 4b is a schematic structural diagram showing sections captured along directions A-A′, C-C′ and E-E′ in FIG. 3 for a structure obtained in Step S6 of a method for fabricating a semiconductor structure according to an embodiment of the present disclosure;

FIGS. 4c to 4i are schematic structural diagrams showing sections captured along directions A-A′, C-C′ and E-E′ in FIG. 3 for a structure obtained in Step S8 of a method for fabricating a semiconductor structure according to an embodiment of the present disclosure;

FIG. 5a is a schematic structural diagram showing sections captured along directions A-A′, C-C′ and E-E′ in FIG. 3 for the structure obtained in Step S2 of a method for fabricating a semiconductor structure according to another embodiment of the present disclosure;

FIG. 5b is a schematic structural diagram showing sections captured along directions A-A′, C-C′ and E-E′ in FIG. 3 for the structure obtained in Step S6 of a method for fabricating a semiconductor structure according to another embodiment of the present disclosure; and

FIGS. 5c to 5k are schematic structural diagrams showing sections captured along directions A-A′, C-C′ and E-E′ in FIG. 3 for the structure obtained in Step S8 of a method for fabricating a semiconductor structure according to another embodiment of the present disclosure.

### REFERENCE NUMBERS IN THE ACCOMPANYING DRAWINGS

substrate 100; cell region 101;
peripheral region 102; first peripheral sub-region 1021; second peripheral sub-region 1022;
bitline 11; wordline 12;
first active region 104; second active region 106; first shallow trench isolation structure 110;
second shallow trench isolation structure 120; wordline trench 15;
peripheral gate trench 16; first peripheral gate trench 161; second peripheral gate trench 162;
gate oxide material layer 171; gate oxide layer 17;
first work function material layer 181; first work function layer 18;
first conductive material layer 191; first conductive layer 19;
primary conductive material layer 201; primary conductive layer 20;
cover insulation material layer 301; cover insulation layer 30;
buried wordline 50; and
buried gate 60; first buried gate 61; and second buried gate 62.

### DETAILED DESCRIPTION

For ease of understanding the present disclosure, the present disclosure will be described more fully hereinafter with reference to the accompanying drawings. Some embodiments of the present disclosure are provided in the accompanying drawings. The present disclosure may, however, be embodied in many different forms and should not be limited to the embodiments set forth herein. Rather, these embodiments are provided so that the present disclosure will be more thorough and complete.

Unless otherwise defined, all technical and scientific terms employed herein have the same meaning as commonly understood by one of ordinary skill in the art to which the present disclosure belongs. The terms employed in the specification of the present disclosure are merely for the purpose of describing some embodiments and are not intended for limiting the present disclosure. As used herein, the term “and/or” includes any and all combinations of one or more of the associated listed items.

It should be understood that when an element or layer is referred to as being “on”, “adjacent to”, “connected to” or “coupled to” other elements or layers, it may be directly on, adjacent to, connected or coupled to the other elements or layers, or intervening elements or layers may be present. In contrast, when an element is referred to as being “directly on”, “directly adjacent to”, “directly connected to” or “directly coupled to” other elements or layers, there are no intervening elements or layers present. It should be understood that although the terms first, second, third, etc. may be employed to describe various elements, components, regions, layers and/or sections, these elements, components, regions, layers and/or sections should not be limited by these terms. These terms are only employed to distinguish one element, component, region, layer or section from another element, component, region, layer or section. Therefore, without departing from the teachings of the present disclosure, a first element, component, region, layer or section discussed below may be represented as a second element, component, region, layer or section.

Spatially relative terms such as “below”, “under”, “lower”, “beneath”, “above”, “upper” and the like may be used herein for ease of description to describe relationships between one element or feature as shown in the figures and another element(s) or feature(s). It should be understood that the spatially relative terms may be intended to encompass different orientations of the device in use or operation in addition to the orientation depicted in the figures. For example, if the device in the figures is turned over, elements or features described as “under”, “beneath” or “below” other elements would then be oriented “above” the other elements or features. Thus, the example term “under”, “below” or “beneath” may encompass both an orientation of above and below. The device may be otherwise oriented (rotated 90 degrees or at other orientations) and the spatially relative descriptors used herein should be interpreted accordingly.

The terminology used herein is for the purpose of describing some embodiments only and is not intended to limit the present disclosure. As used herein, the singular forms of “a”, “one” and “said/the” are also intended to include plural forms, unless the context clearly indicates otherwise. It should also be understood that the terms “comprising” and/or “including”, when used in this specification, determine the presence of the described features, integers, steps, operations, elements and/or components, but do not preclude the presence or addition of one or more other features, integers, steps, operations, elements, components, and/or groups thereof. As used herein, the term “and/or” includes any and all combinations of related listed items.

Embodiments of the present disclosure are described herein with reference to cross-sectional illustrations serving as schematic illustrations of idealized embodiments (and intermediate structures) of the present disclosure. As such, variations from the shapes of the illustrations as a result, for example, of manufacturing techniques and/or tolerances, may be expected. Thus, embodiments of the present disclosure should not be construed as being limited to particular shapes of regions illustrated herein but may include deviations in shapes that result, for example, from manufacturing. Thus, regions illustrated in the figures are schematic in nature and their shapes do not necessarily illustrate the actual shape of a region of a device and do not limit the scope of the present disclosure.

With reference to FIG. 1 to FIG. 5k. It should be noted that the illustrations provided in this embodiment merely illustrate the basic idea of the present disclosure in a schematic manner. Although only the components related to the present disclosure are shown in the drawings rather than the number, shape and dimensional drawing of components in actual implementation. The form, number and proportion of each component in actual implementation may be a random change, and the component layout form may be more complicated.

With reference to FIG. 1, in one embodiment of the present disclosure, a method for fabricating a semiconductor structure is provided, which includes following steps.

Step S2: providing a substrate, the substrate comprising a cell region and a peripheral region positioned at a periphery of the cell region.

Step S4: forming a patterned mask layer on a surface of the substrate, the patterned mask layer being internally provided with a first opening pattern and a second opening pattern, the first opening pattern being positioned in the cell region to define a shape and a location of a wordline trench, and the second opening pattern being positioned in the peripheral region to define a shape and a location of a peripheral gate trench.

Step S6: etching the substrate based on the patterned mask layer to form the wordline trench in the cell region, and to synchronously form the peripheral gate trench in the peripheral region.

Step S8: forming a buried wordline in the wordline trench, and synchronously forming a buried gate in the peripheral gate trench.

As an example, with continued reference to FIG. 1, a substrate is provided, wherein the substrate comprises a cell region and a peripheral region positioned at a periphery of the cell region. A patterned mask layer is formed on a surface of the substrate, wherein the patterned mask layer is internally provided with a first opening pattern and a second opening pattern. The first opening pattern is positioned in the cell region to define a shape and a location of a wordline trench, and the second opening pattern is positioned in the peripheral region to define a shape and a location of a peripheral gate trench. Next, the substrate is etched based on the patterned mask layer to form the wordline trench in the cell region, and synchronously the peripheral gate trench is formed in the peripheral region. Next, a buried wordline is formed in the wordline trench, and synchronously a buried gate is formed in the peripheral gate trench. In the present disclosure, a wordline in the cell region and a gate in the peripheral region at the periphery of the cell region are subject to single exposure and fabricated synchronously, which reduces fabrication costs compared with separately fabricating the gate in the peripheral region where an additional photomask is required. In the present disclosure, the wordline in the cell region and the gate in the peripheral region at the periphery of the cell region both are buried structures, such that it is ensured that the gate sizes of circuits in the peripheral region meet the requirements for circuit integration design while avoiding the increase of the short-channel effects and leakage current of the semiconductor devices.

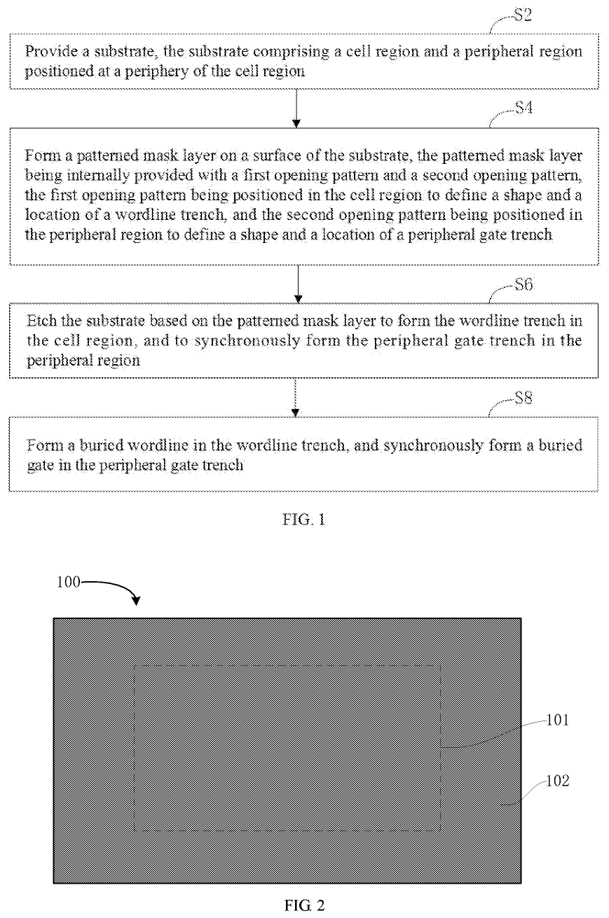

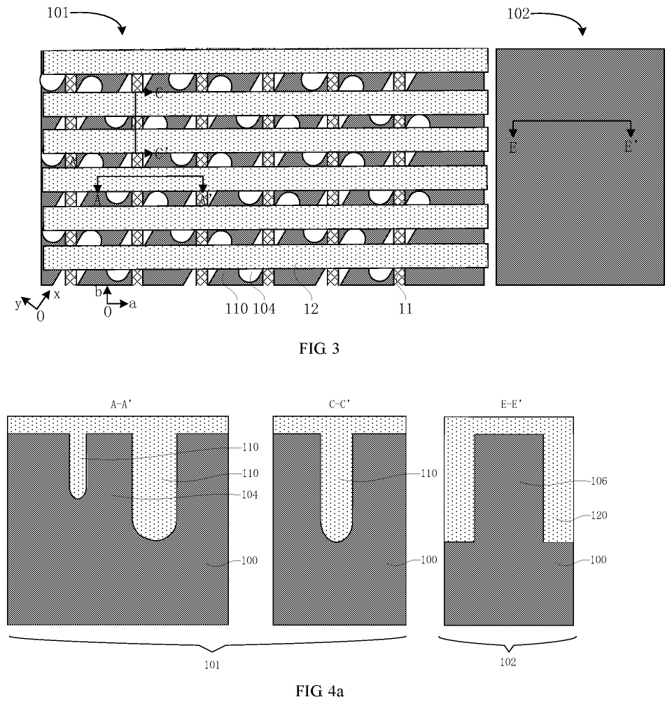

In Step S1, with reference to Step S2 in FIG. 1, FIG. 2 and FIG. 3, a substrate 100 is provided, and the substrate 100 includes a cell region 101 and a peripheral region 102 positioned at a periphery of the cell region 101. It is to be noted that FIG. 2 only schematically illustrates that the peripheral region 102 is positioned at the periphery of the cell region 101, which does not impose any limitation on embodiments of the present disclosure.

As an example, the substrate 100 may be formed of a semiconductor substrate such as a silicon wafer. The substrate 100 may include monocrystal silicon, polycrystalline silicon, or amorphous silicon. The substrate 100 may be selected from at least one of germanium (Ge), silicon germanium (SiGe), silicon carbide (SiC), gallium arsenide (GaAs), indium arsenide (InAs), and indium phosphide (InP). The substrate 100 may include a conductive region. Those skilled in the art may select a type of the substrate based on a type of a transistor formed on the substrate 100. Therefore, the type of the substrate 100 should not limit the scope of protection of the present disclosure.

The cell region 101 may be a high density region where a density of active regions of the cell region 101 is higher, and the peripheral region 102 may be a low density region where the density of the active regions of the peripheral region 102 is lower.

The cell region 101 may be a cell array region of a semiconductor memory device. As an example, a volatile memory cell array such as a dynamic random access memory (DRAM) may be formed in the cell region 101. In some embodiments, a nonvolatile memory cell array such as a flash memory may be formed in the cell region 101. A peripheral circuit electrically connected to a cell array formed in the cell region may be formed in the peripheral region 102. With reference to FIG. 2 and FIG. 3, a method of fabricating a semiconductor structure according to an exemplary embodiment may include forming a first active region 104 and a first shallow trench isolation structure 110 in the cell region 101 of the substrate 100. The first shallow trench isolation structure 110 may confine the first active region 104. The first active region 104 may include an upper surface, wherein a length of the upper surface in a first direction Ox is greater than a length of the upper surface in a second direction Oy, and the first direction Ox is perpendicular to the second direction Oy. It is to be noted that the first active region 104 has a long axis L in the first direction Ox and a short axis S in the second direction Oy. The first active region 104 may include a short sidewall S1 having a same width as the short axis S and a long sidewall L1 parallel to the long axis L. A plurality of first active regions 104 may be formed. The plurality of first active regions 104 may be spaced apart from each other by a first width P1 in the first direction Ox. In addition, the plurality of first active regions 104 may be spaced apart from each other by a second width P2 in the second direction Oy, wherein the second width P2 is less than the first width P1. The plurality of first active regions 104 may be formed repeatedly and regularly in the first direction Ox and the second direction Oy. The first shallow trench isolation structure 110 may include a trench structure, wherein the trench structure may include a first insulating layer 112 and a second insulating layer 114 stacked sequentially from outside to inside. A bitline 11 may extend along a third direction Ob, and a wordline 12 may extend along a fourth direction Oa.

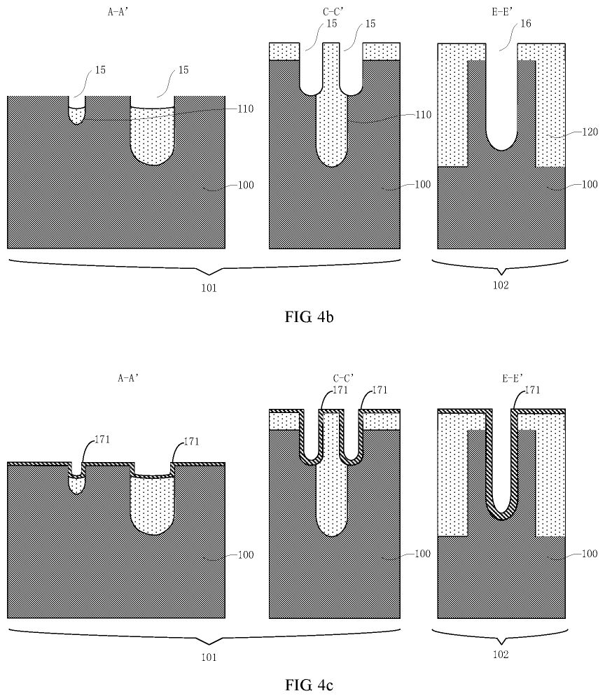

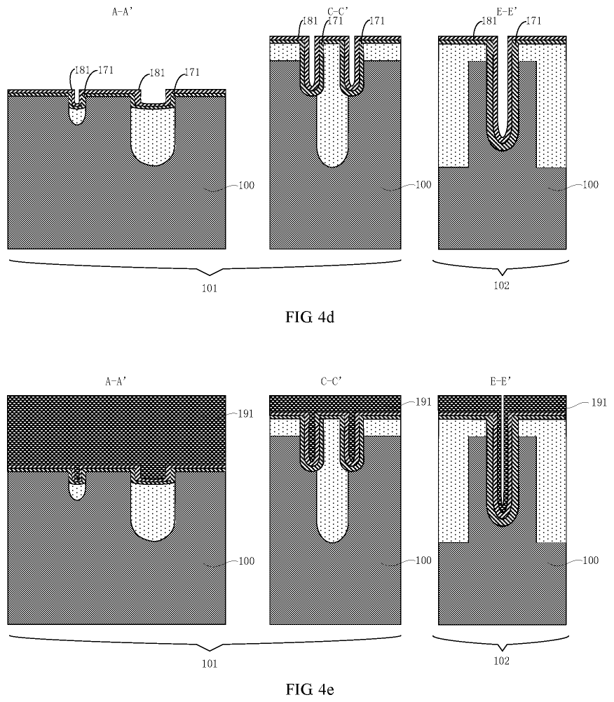

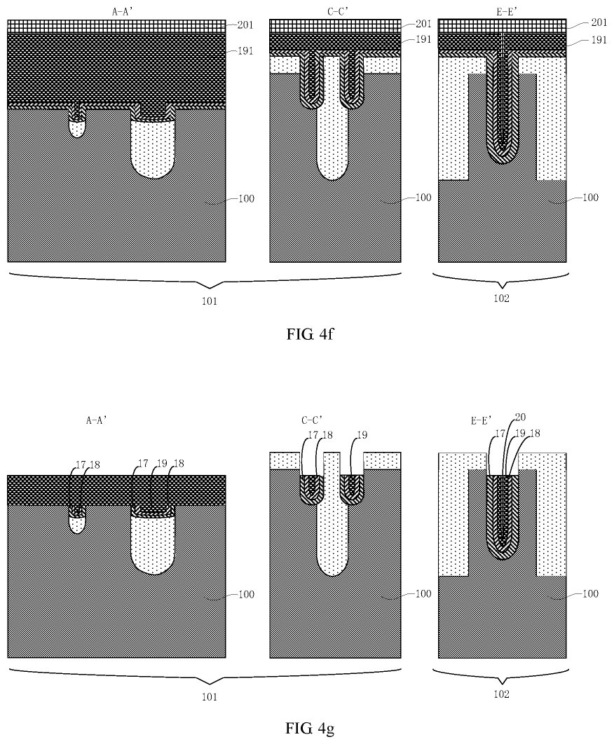

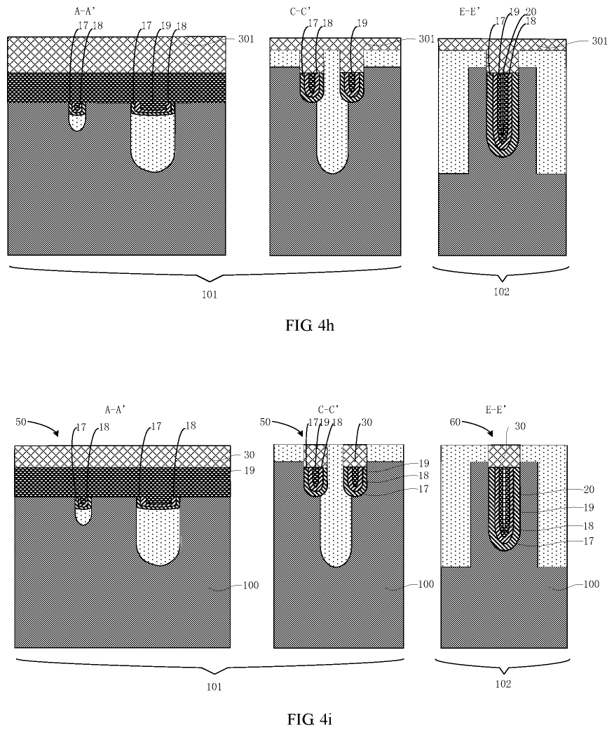

In a semiconductor structure according to an exemplary embodiment, as shown in FIG. 4a, the peripheral region 102 of the substrate 100 has a second active region 106 and a second shallow trench isolation structure 120. The second shallow trench isolation structure 120 may confine the second active region 106. A plurality of second active regions 106 may be formed. The plurality of second active regions 106 may be spaced apart from each other by a third width P3, or the plurality of second active regions 106 may be spaced apart from each other by a fourth width P4. In an exemplary embodiment of the present disclosure, the second shallow trench isolation structure 120 may include an insulating layer liner (not shown) and a gap-filling insulating layer (not shown) stacked sequentially from outside to inside.

As an example, Step S2 may include following steps.

Step S22: forming a first mask layer (not shown) on an upper surface of the substrate 100.

Step S24: coating a first photoresist layer (not shown) on the upper surface of the first mask layer (not shown), and patterning the first photoresist layer to form a patterned photoresist layer (not shown).

Step S26: etching the first mask layer based on the patterned photoresist layer to form the patterned mask layer (not shown). The patterned mask layer (not shown) is internally provided with a first opening pattern and a second opening pattern, wherein the first opening pattern is positioned in the cell region to define a shape and a location of a wordline trench, and the second opening pattern is positioned in the peripheral region to define a shape and a location of a peripheral gate trench.

Step S214: removing the patterned photoresist layer.

As an example, the formed patterned mask layer may include a hard mask layer. The hard mask layer may have a single-layer structure or a multilayer stacked structure, and may be made from silicon oxide. Next, a photoresist is coated on the hard mask layer, and a patterned photoresist layer is formed through a series of steps such as exposure and development. The patterned photoresist layer defines the shape and the location of the wordline trench, and defines the shape and the location of the peripheral gate trench. Next, the hard mask layer is etched based on the patterned photoresist layer to form a patterned mask layer, and then the patterned photoresist layer is removed. Of course, in other embodiments of the present disclosure, the patterned photoresist layer may also be remained in the process of forming the patterned mask layer, and the patterned photoresist layer is removed after the substrate 100 is etched.

As an example, in one embodiment of the present disclosure, the patterned mask layer is formed by means of a self-aligned double patterning technology (SADP). That is, after one photoetching process is completed, non-photoetching processing steps (such as thin film deposition, and etching, etc.) are employed in succession to implement spatial frequency multiplication of a photoetched pattern. Finally, excess patterns are removed by means of another photoetching and etching. Reference may be made to the issued patent “ACTIVE REGION ARRAY AND FORMING METHOD THEREOF, AND SEMICONDUCTOR DEVICE AND FORMING METHOD THEREOF” (CN110875313A) for a technology of how to form a patterned mask layer by means of SADP, detailed contents thereof are not to be repeated herein.

As an example, in one embodiment of the present disclosure, the patterned mask layer may be formed by means of a deep ultraviolet lithography technology. The patterned mask layer is formed by means of an extreme ultraviolet (EUV) photoetching machine through the deep ultraviolet lithography technology. A buried wordline pattern in the cell region and a buried gate pattern in the peripheral region at the periphery of the cell region are subject to single exposure and are synchronously fabricated to form a buried gate in the peripheral region, which reduces technological processes and device manufacturing costs. In this way, it is ensured that the gate sizes of circuits in the peripheral region meet the requirements for circuit integration design while avoiding the increase of the short-channel effects and leakage current of the semiconductor devices.

As an example, in one embodiment of the present disclosure, with reference to Step S6 in FIG. 1 and FIGS. 4a to 4b, Step S6 may include the following steps.

Based on the patterned mask layer, the upper surface of the substrate 100 is etched by means of a dry etch process or a wet etch process, to form a wordline trench 15 in the cell region 101 and simultaneously form a peripheral gate trench 16 in the peripheral region 102, as shown in FIG. 4b.

As an example, in Step S6, a plurality of wordline trenches 15 regularly spaced apart from each other may be synchronously formed, and a plurality of peripheral gate trenches 16 regularly spaced apart from each other may be synchronously formed.

In Step S8, with reference to Step S8 in FIG. 1 and FIGS. 4c to 4i, forming a buried wordline in the wordline trench, and synchronously forming a buried gate in the peripheral gate trench include following steps.

Step S82: forming a gate oxide layer 17 on an inner surface of the wordline trench 15 and an inner surface of the peripheral gate trench 16.

Step S84: forming a first work function layer 18 on a surface of the gate oxide layer 17, wherein the first work function layer 18 covers the gate oxide layer 17.

Step S86: forming a first conductive layer 19 on a surface of the first work function layer 18, wherein the first conductive layer 19 is voidlessly filled into the wordline trench 15, and a gap is provided on an inner side of the first conductive layer 19 positioned in the peripheral gate trench 16.

Step S88: forming a primary conductive layer 20 in the gap on the inner side of the first conductive layer 19.

Step S810: filling in the wordline trench 15 and the peripheral gate trench 16 and forming a cover insulation layer 30 to form the buried wordline in the wordline trench and synchronously form the buried gate in the peripheral gate trench.

As an example, with continued reference to Step S8 in FIG. 1 and FIG. 4c, in Step S82, a gate oxide material layer 171 may be formed on the inner surface of the wordline trench 15 and the inner surface of the peripheral gate trench 16 by means of at least one of an atomic layer deposition process, an in-situ steam generation process, and a rapid thermal oxidation process. For example, in this embodiment, the gate oxide material layer 171 may be formed on the inner surface of the wordline trench 15 and the inner surface of the peripheral gate trench 16 by means of the in-situ steam generation process. The gate oxide material layer 171 overs the inner surface of the wordline trench 15, the inner surface of the peripheral gate trench 16, and the upper surface of the substrate 100.

As an example, with continued reference to Step S8 in FIG. 1 and FIG. 4d, in Step S84, a first work function material layer 181 may be formed on a surface of the gate oxide material layer 171 by means of at least one of the atomic layer deposition process, the in-situ steam generation process, and the rapid thermal oxidation process. The first work function material layer 181 covers the gate oxide material layer 171. For example, in this embodiment, the first work function material layer 181 may be formed on the upper surface of the gate oxide material layer 171 by means of the atomic layer deposition process.

As an example, with continued reference to Step S8 in FIG. 1 and FIG. 4e, a first conductive material layer 191 may be formed on the surface of the first work function material layer 181 by means of the deposition process in Step S86. The first conductive material layer 191 is voidlessly filled into the wordline trench 15, and a gap is provided on an inner side of the first conductive material layer 191 positioned in the peripheral gate trench 16.

As an example, with continued reference to FIG. 4e, the process for forming the first work function material layer 181 in Step S86 may be at least one of a high density plasma (HDP) deposition process and a plasma enhanced deposition process. In the present disclosure, the first conductive material layer 191 may be formed on the surface of the first work function material layer 181 by means of the HDP deposition process. The first conductive material layer 191 is voidlessly filled into the wordline trench 15, and a gap is provided on the inner side of the first conductive material layer 191 positioned in the peripheral gate trench 16.

As an example, with continued reference to Step S8 in FIG. 1 and FIG. 4f, a primary conductive material layer 201 may be filled into the gap of the inner side of the first conductive material layer 191 by means of a deposition process in Step S88. For example, in the present disclosure, the primary conductive material layer 201 may be filled into the gap of the inner side of the first conductive material layer 191 by means of the HDP deposition process.

As an example, with continued reference to Step S8 in FIG. 1 and FIG. 4g, after the step of forming the primary conductive material layer 201, the method also includes following steps.

Step S89: etching back the obtained structure to remove the primary conductive material layer 201, the first conductive material layer 191, the first work function material layer 181 and the gate oxide material layer 171 above the substrate 100, and synchronously removing a part of the first conductive material layer 191, a part of the first work function material layer 181 and a part of the gate oxide material layer 171 in the wordline trench 15, and removing a part of the primary conductive material layer 201, a part of the first conductive material layer 191, a part of the first work function material layer 181 and a part of the gate oxide material layer 171 in the peripheral gate trench 16. The first conductive material layer 191 remained in the wordline trench 15 constitutes the first conductive layer 19, the first work function material layer 181 remained in the wordline trench 15 constitutes the first work function layer 18, and the gate oxide material layer 171 remained in the wordline trench 15 constitutes the gate oxide layer 17. The primary conductive material layer 201 remained in the peripheral gate trench 16 constitutes the primary conductive layer 20, the first conductive material layer 191 remained in the peripheral gate trench 16 constitutes the first conductive layer 19, the first work function material layer 181 remained in the peripheral gate trench 16 constitutes the first work function layer 18, and the gate oxide material layer 171 remained in the peripheral gate trench 16 constitutes the gate oxide layer 17. Top surfaces of the first conductive layer 19, the first work function layer 18 and the gate oxide layer 17 in the wordline trench 15 are lower than a top surface of the wordline trench 15. Top surfaces of the primary conductive layer 20, the first conductive layer 19, the first work function layer 18 and the gate oxide layer 17 in the peripheral gate trench 16 are lower than a top surface of the peripheral gate trench 16.

As an example, with continued reference to Step S8 in FIG. 1 and FIG. 4h, a cover insulation material layer 301 may be formed and filled into the wordline trench 15 and the peripheral gate trench 16 respectively by means of the deposition process in Step S810, to form the buried wordline in the wordline trench and to synchronously form the buried gate in the peripheral gate trench.

As an example, with continued reference to Step S8 in FIG. 1 and FIG. 4i, in Step S810, the cover insulation material layer 301 positioned on the upper surface of the substrate 100, the cover insulation material layer 301 positioned above the wordline trench 15 and the cover insulation material layer 301 positioned above the peripheral gate trench 16 may be removed by means of a chemical mechanical polishing process, such that the upper surface of the substrate 100 is planarized. The cover insulation material layer 301 remained in the wordline trench 15 and the cover insulation material layer 301 remained in the peripheral gate trench 16 constitute the cover insulation layer 30, to form the buried wordline in the wordline trench 15 and synchronously form the buried gate in the peripheral gate trench 16.

As an example, in one embodiment of the present disclosure, forming the first work function layer 18 on the surface of the gate oxide layer 17 in Step S84 may include following steps.

Step S842: forming a hafnium silicate layer (not shown) on the surface of the gate oxide material layer 171.

Step S844: forming a lanthanum oxide layer (not shown) on a surface of the hafnium silicate layer.

Step S846: performing annealing treatment on a structure obtained, such that lanthanum diffuses onto the hafnium silicate layer to form a lanthanum-doped hafnium silicate layer.

As an example, in one embodiment of the present disclosure, after the lanthanum-doped hafnium silicate layer is formed, the method also includes: removing the lanthanum oxide layer.

In the method for fabricating a semiconductor structure according to the above embodiment, the hafnium silicate layer is formed on the surface of the gate oxide layer, and the lanthanum oxide layer is formed on the surface of the hafnium silicate layer. Next, annealing treatment is performed on the structure obtained, such that lanthanum diffuses onto the hafnium silicate layer to form the lanthanum-doped hafnium silicate layer. In this way, a gate having a higher dielectric constant is fabricated, and it is convenient to adjust a threshold value of the gate.

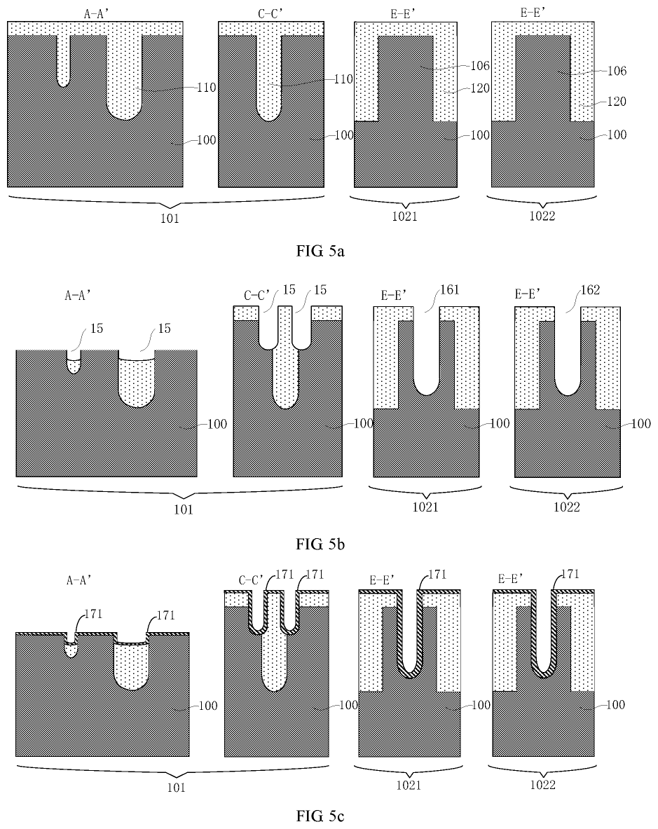

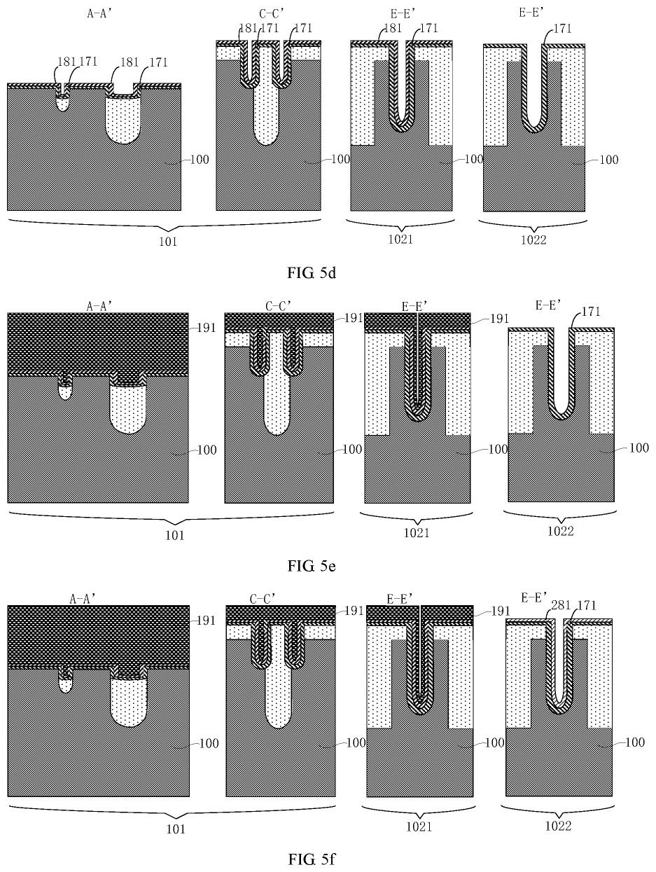

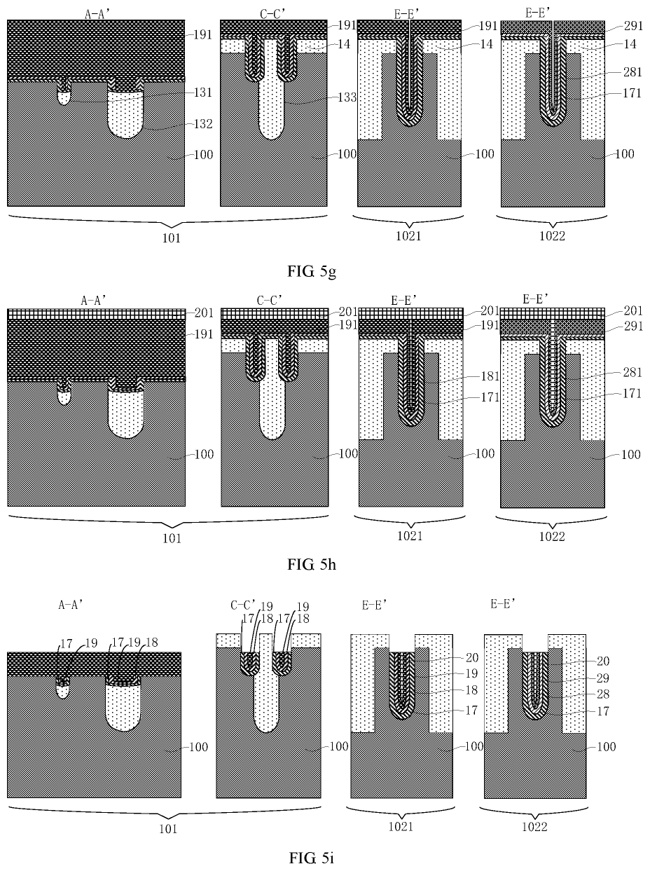

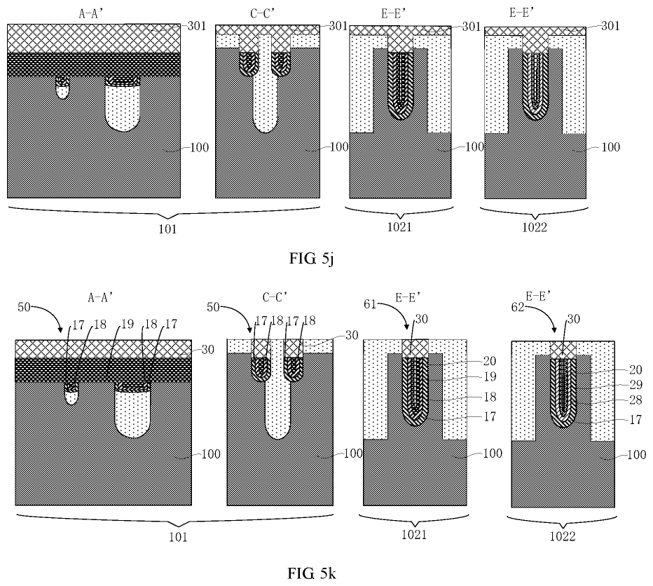

As an example, in another embodiment of the present disclosure, with reference to FIG. 5k, the peripheral gate trench 16 comprises a first peripheral gate trench 161 and a second peripheral gate trench 162. The formed buried gate comprising the gate oxide layer 17, the first work function layer 18, the first conductive layer 19, the primary conductive layer 20 and the cover insulation layer 30 is a first buried gate, and the first buried gate is positioned in the first peripheral gate trench 161. After the first conductive layer 19 is formed on the surface of the first work function layer 18, and before the primary conductive layer 20 is formed, the method further comprises: forming a second work function layer 28 on a surface of the gate oxide layer 17, and forming a second conductive layer 29 on a surface of the second work function layer 28, a gap being provided on an inner side of the second conductive layer 29. The primary conductive layer 20 is synchronously formed in the gap on the inner side of the first conductive layer 19 and in the gap on the inner side of the second conductive layer 29. The cover insulation layer 30 is synchronously formed in the wordline trench, the first peripheral gate trench 161, the first peripheral gate trench 161, and the second peripheral gate trench 162, to form a second buried gate in the second peripheral gate trench while the buried gate wordline is formed in the wordline trench 15 and the first buried gate is formed in the first peripheral gate trench 161.

As an example, with continued reference to Step S6 in FIG. 1 and FIGS. 5a to 5b, Step S6 may include the following step.

Based on the patterned mask layer, the upper surface of the substrate 100 is etched by means of the dry etch process or the wet etch process, to form the wordline trench 15 in the cell region 101 and simultaneously form the peripheral gate trench 16 in the peripheral region 102. The peripheral gate trench 16 includes a first peripheral gate trench 161 and a second peripheral gate trench 162.

As an example, in Step S6, a plurality of wordline trenches 15 regularly spaced apart from each other may be synchronously formed, and a plurality of peripheral gate trenches 16 regularly spaced apart from each other may be synchronously formed. Each of the plurality of peripheral gate trenches 16 includes a first peripheral gate trench 161 and a second peripheral gate trench 162.

In Step S8, with reference to Step S8 in FIG. 1 and FIG. 5k, forming a buried wordline in the wordline trench, and synchronously forming a buried gate in the peripheral gate trench include following steps.

Step S821: forming a gate oxide material layer 171 on an inner surface of the wordline trench 15, an inner surface of the first peripheral gate trench 161, and an inner surface of the second peripheral gate trench 162, respectively.

Step S841: forming a first work function material layer 181 on a surface of the gate oxide material layer 171, wherein the first work function material layer 181 covers the gate oxide material layer 171.

Step S861: forming a first conductive material layer 191 on a surface of the first work function material layer 181 in the first peripheral gate trench 161, wherein the first conductive material layer 191 is voidlessly filled into the wordline trench 15, and a gap is provided on an inner side of the first conductive material layer 191 positioned in the first peripheral gate trench 161.

Step S871: forming a second work function material layer 281 on the surface of the gate oxide material layer 171 in the second peripheral gate trench 162, wherein the second work function material layer 281 covers the surface of the gate oxide material layer 171 in the second peripheral gate trench 162.

Step S872: forming a second conductive material layer 291 on the surface of the second work function material layer 281 in the second peripheral gate trench 162, wherein the second conductive material layer 291 covers the second work function material layer 281 in the second peripheral gate trench 162, and a gap is provided on an inner side of the second conductive material layer 291 in the second peripheral gate trench 162.

Step S881: forming a primary conductive material layer 201 in the gaps on the inner sides of the first conductive material layer 191 and the second conductive material layer 291.

Step S891: etching back the obtained structure to remove the primary conductive material layer 201, the first conductive material layer 191, the first work function material layer 181 and the gate oxide material layer 171 above the substrate 100, and synchronously removing a part of the first conductive material layer 191, a part of the first work function material layer 181 and a part of the gate oxide material layer 171 in the wordline trench 15, removing a part of the primary conductive material layer 201, a part of the first conductive material layer 191, a part of the first work function material layer 181 and a part of the gate oxide material layer 171 in the first peripheral gate trench 161, and removing a part of the primary conductive material layer 201, a part of the second conductive material layer 291, a part of the second work function material layer 281 and a part of the gate oxide material layer 171 in the second peripheral gate trench 162. The first conductive material layer 191 remained in the wordline trench 15 constitutes the first conductive layer 19, the first work function material layer 181 remained in the wordline trench 15 constitutes the first work function layer 18, and the gate oxide material layer 171 remained in the wordline trench 15 constitutes the gate oxide layer 17. The primary conductive material layer 201 remained in the first peripheral gate trench 161 constitutes the primary conductive layer 20, the first conductive material layer 191 remained in the first peripheral gate trench 161 constitutes the first conductive layer 19, the first work function material layer 181 remained in the first peripheral gate trench 161 constitutes the first work function layer 18, and the gate oxide material layer 171 remained in the first peripheral gate trench 161 constitutes the gate oxide layer 17. The primary conductive material layer 201 remained in the second peripheral gate trench 162 constitutes the primary conductive layer 20, the second conductive material layer 291 remained in the second peripheral gate trench 162 constitutes the second conductive layer 29, the second work function material layer 281 remained in the second peripheral gate trench 162 constitutes the second work function layer 28, and the gate oxide material layer 171 remained in the second peripheral gate trench 162 constitutes the gate oxide layer 17. Top surfaces of the first conductive layer 19, the first work function layer 18 and the gate oxide layer 17 in the wordline trench 15 are lower than a top surface of the wordline trench 15. Top surfaces of the primary conductive layer 20, the first conductive layer 19, the first work function layer 18 and the gate oxide layer 17 in the first peripheral gate trench 161 are lower than a top surface of the peripheral gate trench 16. Top surfaces of the primary conductive layer 20, the second conductive layer 29, the second work function layer 28 and the gate oxide layer 17 in the second peripheral gate trench 162 are lower than a top surface of the second peripheral gate trench 162.

Step S811: filling in the wordline trench 15, the first peripheral gate trench 161 and the second peripheral gate trench 162 and forming the cover insulation layer 30 to form the buried wordline in the wordline trench and synchronously form the buried gate in the peripheral gate trench.

As an example, with continued reference to Step S8 in FIG. 1 and FIGS. 5i-5k, a cover insulation material layer 301 may be formed and filled into the wordline trench 15, the first peripheral gate trench 161 and the second peripheral gate trench 162 respectively by means of the deposition process in Step S811, to form the buried wordline in the wordline trench and to synchronously form the buried gate in the peripheral gate trench.

As an example, with continued reference to Step S8 in FIG. 1 and FIGS. 5I-5k, the cover insulation material layer 301 positioned on the upper surface of the substrate 100, the cover insulation material layer 301 positioned above the wordline trench 15, the cover insulation material layer 301 positioned above the first peripheral gate trench 161 and the cover insulation material layer 301 positioned above the second peripheral gate trench 162 may be removed by means of the chemical mechanical polishing process in Step S811, such that the upper surface of the substrate 100 is planarized. The cover insulation material layer 301 remained in the wordline trench 15, the cover insulation material layer 301 remained in the first peripheral gate trench 161 and the cover insulation material layer 301 remained in the second peripheral gate trench 162 constitute the cover insulation layer 30, to form the buried wordline in the wordline trench 15 and synchronously form the buried gate in the peripheral gate trench 16.

As an example, in one embodiment of the present disclosure, forming a second work function material layer 281 on a surface of the gate oxide material layer 171 in the second peripheral gate trench 162 in Step S871 may include following steps.

Step S8712: forming a hafnium silicate layer (not shown) on the surface of the gate oxide material layer 171 in the second peripheral gate trench 162.

Step S8714: forming an aluminum oxide layer (not shown) on a surface of the hafnium silicate layer.

Step S8716: performing annealing treatment on a structure obtained, such that aluminum diffuses onto the hafnium silicate layer to form an aluminum-doped hafnium silicate layer.

As an example, in one embodiment of the present disclosure, after the aluminum-doped hafnium silicate layer is formed, the method also includes: removing the aluminum oxide layer.

In the method for fabricating a semiconductor structure according to the above embodiment, the hafnium silicate layer is formed on the surface of the gate oxide layer, and the aluminum oxide layer is formed on the surface of the hafnium silicate layer. Next, annealing treatment is performed on the structure obtained, such that aluminum diffuses onto the hafnium silicate layer to form the aluminum-doped hafnium silicate layer. In this way, a gate having a higher dielectric constant is fabricated, and it is convenient to adjust a threshold value of the gate.

As an example, in one embodiment of the present disclosure, the gate oxide layer 17 may include, but is not limited to, a silicon oxide layer.

As an example, in one embodiment of the present disclosure, the cover insulation layer 30 may include, but is not limited to, a silicon nitride layer.

As an example, with reference to FIG. 4i, the semiconductor structure according to an exemplary embodiment includes a substrate 100 and a buried wordline 50 and a buried gate 60 formed in the substrate 100. The substrate 100 includes a cell region 101 and a peripheral region 102 positioned at the periphery of the cell region 101. The buried wordline 50 is positioned in the cell region 101, and the buried gate 60 is positioned in the peripheral region 102.

In some embodiments, with continued reference to FIG. 4i, the wordline in the cell region 101 and the gate in the peripheral region 102 at the periphery of the cell region 101 both are buried structures, such that it is ensured that the gate sizes of circuits in the peripheral region 102 meet the requirements for circuit integration design while avoiding the increase of the short-channel effects and leakage current of the semiconductor devices.

As an example, with reference to FIG. 5k, in the semiconductor structure according to an exemplary embodiment, the buried gate includes a first buried gate 61 and a second buried gate 62, wherein the first buried gate 61 is positioned in a first peripheral sub-region 1021, and the second buried gate 62 is positioned in a second peripheral sub-region 1022. The buried wordline 50 includes a gate oxide layer 17, a first work function layer 18, a first conductive layer 19, and a cover insulation layer 30. In the buried wordline 50, the gate oxide layer 17, the first work function layer 18 and the first conductive layer 19 are sequentially stacked from outside to inside. The cover insulation layer 30 is positioned on the upper surfaces of the gate oxide layer 17, the first work function layer 18 and the first conductive layer 19. The first buried gate 61 includes: the gate oxide layer 17, the first work function layer 18, the first conductive layer 19, a primary conductive layer 20, and the cover insulation layer 30. In the first buried gate 61, the gate oxide layer 17, the first work function layer 18, the first conductive layer 19 and the primary conductive layer 20 are sequentially stacked from the outside to the inside. The cover insulation layer 30 is positioned on the upper surfaces of the gate oxide layer 17, the first work function layer 18, the first conductive layer 19, and the primary conductive layer 20. The second buried gate 62 includes: the gate oxide layer 17, a second work function layer 28, a second conductive layer 29, the primary conductive layer 20, and the cover insulation layer 30. In the second buried gate 62, the gate oxide layer 17, the second work function layer 28, the second conductive layer 29 and the primary conductive layer 20 are sequentially stacked from the outside to the inside. The cover insulation layer 30 is positioned on the upper surfaces of the gate oxide layer 17, the second work function layer 28, the second conductive layer 29, and the primary conductive layer 20.

As an example, with continued reference to FIG. 5k, in one embodiment of the present disclosure, the first work function layer 18 includes a lanthanum-doped hafnium silicate layer, and the second work function layer 28 includes an aluminum-doped hafnium silicate layer. In this way, the dielectric constant of a gate of a semiconductor device is improved, and it is convenient to adjust the threshold value of the gate.

As an example, with continued reference to FIG. 5k, in one embodiment of the present disclosure, the first work function layer 18 further includes a lanthanum oxide layer (not shown), and the lanthanum oxide layer is positioned between the lanthanum-doped hafnium silicate layer (not shown) and the first conductive layer 19. The second work function layer 28 also includes an aluminum oxide layer (not shown), and the aluminum oxide layer is positioned between the aluminum-doped hafnium silicate layer (not shown) and the second conductive layer 29. In this way, the dielectric constant of the gate of the semiconductor device is improved, and it is convenient to adjust the threshold value of the gate.

As an example, with continued reference to FIG. 5k, in one embodiment of the present disclosure, the gate oxide layer 17 includes a silicon oxide layer.

As an example, with continued reference to FIG. 5k, in one embodiment of the present disclosure, the first conductive layer 19 and the second conductive layer 29 are both titanium nitride layers, and the primary conductive layer 20 is a tungsten layer.

As an example, with continued reference to FIG. 5k, in one embodiment of the present disclosure, the first conductive layer 19 and the second conductive layer 29 are both molybdenum nitride layers, and the primary conductive layer 20 is a molybdenum layer.

In conclusion, the present disclosure provides a method for fabricating a semiconductor structure, and a semiconductor structure. A substrate is provided, wherein the substrate comprises a cell region and a peripheral region positioned at a periphery of the cell region. A patterned mask layer is formed on a surface of the substrate, wherein the patterned mask layer is internally provided with a first opening pattern and a second opening pattern. The first opening pattern is positioned in the cell region to define a shape and a location of a wordline trench, and the second opening pattern is positioned in the peripheral region to define a shape and a location of a peripheral gate trench. Next, the substrate is etched based on the patterned mask layer to form the wordline trench in the cell region, and synchronously the peripheral gate trench is formed in the peripheral region. Next, a buried wordline is formed in the wordline trench, and synchronously a buried gate is formed in the peripheral gate trench. In the present disclosure, a wordline in the cell region and a gate in the peripheral region at the periphery of the cell region are subject to single exposure and fabricated synchronously, which reduces fabrication costs compared with separately fabricating the gate in the peripheral region where an additional photomask is required. In the present disclosure, the wordline in the cell region and the gate in the peripheral region at the periphery of the cell region both are buried structures, such that it is ensured that the gate sizes of circuits in the peripheral region meet the requirements for circuit integration design while avoiding the increase of the short-channel effects and leakage current of the semiconductor devices.

It is to be noted that the above embodiments are intended for purposes of illustration only and are not intended to limit the present disclosure.

It should be understood that unless expressly stated herein, the execution of these steps is not strictly limited in sequence, and these steps may be performed in other orders. Moreover, at least some of the steps may include a plurality of sub-steps or a plurality o stages, which are not necessarily performed at the same moment, but may be executed at different moments, and the order of execution of these sub-steps or stages is not necessarily performed sequentially, but may be performed alternately or alternately with at least a portion of the sub-steps or stages of other steps or other steps.

The embodiments in the specification are described in a progressive manner. Each embodiment is focused on difference from other embodiments. And cross reference is available for identical or similar parts among different embodiments.

Technical features of the above embodiments may be arbitrarily combined. For simplicity, all possible combinations of the technical features in the above embodiments are not described. However, as long as the combination of these technical features is not contradictory, it shall be deemed to be within the scope recorded in this specification.

The above embodiments merely express a plurality of implementations of the present disclosure, and descriptions thereof are relatively concrete and detailed. However, these embodiments are not thus construed as limiting the patent scope of the present disclosure. It is to be pointed out that for persons of ordinary skill in the art, some modifications and improvements may be made under the premise of not departing from a conception of the present disclosure, which shall be regarded as falling within the scope of protection of the present disclosure. Thus, the scope of protection of the present disclosure shall be subject to the appended claims.

What is claimed is:

1. A method for fabricating a semiconductor structure, comprising:
providing a substrate, the substrate comprising a cell region and a peripheral region positioned at a periphery of the cell region;
forming a patterned mask layer on a surface of the substrate, the patterned mask layer being internally provided with a first opening pattern and a second opening pattern, the first opening pattern being positioned in the cell region to define a shape and a location of a wordline trench, and the second opening pattern being positioned in the peripheral region to define a shape and a location of a peripheral gate trench;
etching the substrate based on the patterned mask layer to form the wordline trench in the cell region, and to synchronously form the peripheral gate trench in the peripheral region; and
forming a buried wordline in the wordline trench, and synchronously forming a buried gate in the peripheral gate trench.

2. The method for fabricating a semiconductor structure according to claim 1, wherein the patterned mask layer is formed by means of a self-aligned double patterning technology or a deep ultraviolet lithography technology.

3. The method for fabricating a semiconductor structure according to claim 1, wherein forming a buried wordline in the wordline trench, and synchronously forming a buried gate in the peripheral gate trench comprise:
forming a gate oxide layer on an inner surface of the wordline trench and an inner surface of the peripheral gate trench;
forming a first work function layer on a surface of the gate oxide layer, the first work function layer covering the gate oxide layer;
forming a first conductive layer on a surface of the first work function layer, the first conductive layer being voidlessly filled into the wordline trench, and a gap being provided on an inner side of the first conductive layer positioned in the peripheral gate trench;
forming a primary conductive layer in the gap on the inner side of the first conductive layer; and
filling in the wordline trench and the peripheral gate trench and forming a cover insulation layer to form the buried wordline in the wordline trench and synchronously form the buried gate in the peripheral gate trench.

4. The method for fabricating a semiconductor structure according to claim 3, wherein forming a first work function layer on a surface of the gate oxide layer comprises:
forming a hafnium silicate layer on the surface of the gate oxide layer;
forming a lanthanum oxide layer on a surface of the hafnium silicate layer; and
performing annealing treatment on a structure obtained, such that lanthanum diffuses onto the hafnium silicate layer to form a lanthanum-doped hafnium silicate layer.

5. The method for fabricating a semiconductor structure according to claim 4, wherein after the lanthanum-doped hafnium silicate layer is formed, the method further comprises:
removing the lanthanum oxide layer.

6. The method for fabricating a semiconductor structure according to claim 3, wherein the peripheral gate trench comprises a first peripheral gate trench and a second peripheral gate trench;
the formed buried gate comprising the gate oxide layer, the first work function layer, the first conductive layer, the primary conductive layer and the cover insulation layer is a first buried gate, the first buried gate being positioned in the first peripheral gate trench;
after the first conductive layer is formed on the surface of the first work function layer, and before the primary conductive layer is formed, the method further comprises:
forming a second work function layer on a surface of the gate oxide layer, and forming a second conductive layer on a surface of the second work function layer, a gap being provided on an inner side of the second conductive layer; and
the primary conductive layer is synchronously formed in the gap on the inner side of the first conductive layer and in the gap on the inner side of the second conductive layer; the cover insulation layer is synchronously formed in the wordline trench, the first peripheral gate trench and the second peripheral gate trench, to form a second buried gate in the second peripheral gate trench while a buried gate wordline is formed in the wordline trench and the first buried gate is formed in the first peripheral gate trench.

7. The method for fabricating a semiconductor structure according to claim 6, wherein forming a second work function layer on a surface of the gate oxide layer in the second peripheral gate trench comprises:
forming a hafnium silicate layer on the surface of the gate oxide layer;
forming an aluminum oxide layer on a surface of the hafnium silicate layer; and
performing annealing treatment on a structure obtained, such that aluminum diffuses onto the hafnium silicate layer to form an aluminum-doped hafnium silicate layer.

8. The method for fabricating a semiconductor structure according to claim 7, wherein after the aluminum-doped hafnium silicate layer is formed, the method further comprises:
removing the aluminum oxide layer.

9. The method for fabricating a semiconductor structure according to claim 6, wherein the gate oxide layer is formed by means of an in-situ steam generation process.

10. A semiconductor structure, comprising:
a substrate, the substrate comprising a cell region and a peripheral region positioned at a periphery of the cell region;
a buried wordline, positioned in the cell region; and
a buried gate, positioned in the peripheral region.

11. The semiconductor structure according to claim 10, wherein the buried gate comprises a first buried gate and a second buried gate; and the buried wordline comprises a gate oxide layer, a first work function layer, a first conductive layer, and a cover insulation layer;
the gate oxide layer, the first work function layer and the first conductive layer are stacked in sequence from outside to inside in the buried wordline, the cover insulation layer being positioned on upper surfaces of the gate oxide layer, of the first work function layer, and of the first conductive layer;
the first buried gate comprises: a gate oxide layer, a first work function layer, a first conductive layer, a primary conductive layer, and a cover insulation layer;
the gate oxide layer, the first work function layer, the first conductive layer and the primary conductive layer are stacked in sequence from outside to inside in the first buried gate, the cover insulation layer being positioned on upper surfaces of the gate oxide layer, of the first work function layer, of the first conductive layer, and of the primary conductive layer;
the second buried gate comprises: a gate oxide layer, a second work function layer, a second conductive layer, a primary conductive layer, and a cover insulation layer; and
the gate oxide layer, the second work function layer, the second conductive layer and the primary conductive layer are stacked in sequence from outside to inside in the second buried gate, the cover insulation layer being positioned on upper surfaces of the gate oxide layer, of the second work function layer, of the second conductive layer, and of the primary conductive layer.

12. The semiconductor structure according to claim 11, wherein the first work function layer comprises a lanthanum-doped hafnium silicate layer, and the second work function layer comprises an aluminum-doped hafnium silicate layer.

13. The semiconductor structure according to claim 12, wherein the first work function layer further comprises a lanthanum oxide layer positioned between the lanthanum-doped hafnium silicate layer and the first conductive layer; and
the second work function layer further comprises an aluminum oxide layer positioned between the aluminum-doped hafnium silicate layer and the second conductive layer.

14. The semiconductor structure according to claim 11, wherein the gate oxide layer comprises a silicon oxide layer.

15. The semiconductor structure according to claim 11, wherein the first conductive layer and the second conductive layer are both titanium nitride layers, and the primary conductive layer is a tungsten layer; or
the first conductive layer and the second conductive layer are both molybdenum nitride layers, and the primary conductive layer is a molybdenum layer.
